(19) United States
(12) Patent Application Publication
(10) Pub. No.: US 2019/0372553 A1
(43) Pub. Date: Dec. 5, 2019

(54) SURFACE ACOUSTIC WAVE DEVICE

(71) Applicant: WISOL CO., LTD., Osan-si (KR)

(72) Inventors: Sang Hoon MYEONG, Osan-si (KR); Chang Min LEE, Osan-si (KR); Sang Ki BAE, Osan-si (KR)

(21) Appl. No.: 16/429,447

(22) Filed: Jun. 3, 2019

(30) Foreign Application Priority Data
Jun. 4, 2018 (KR) 10-2018-0064234

(51) Int. Cl. H03H 9/02

(52) U.S. Cl. CPC H03H 9/02992; H03H 9/02574; H03H 9/02622

(57) ABSTRACT

A surface acoustic wave device includes: a substrate; an electrode disposed on the substrate in a first direction; a dummy bar disposed to be spaced apart from the electrode by a predetermined distance in the first direction; and an additional film formed on the dummy bar, wherein the electrode and the dummy bar are disposed in plurality in parallel in a second direction perpendicular to the first direction, and the dummy bars are alternately disposed on a left side or a right side of the electrode to be spaced apart from the electrode by the predetermined distance, and the additional film is formed on the predetermined distance between the electrode and the dummy bar and on the plurality of dummy bars.

### CROSS-REFERENCE TO RELATED APPLICATION

The present application claims priority to Korean Patent Application No. 10-2018-0064234, filed Jun. 4, 2018, the disclosure of which is incorporated by reference herein in its entirety.

### BACKGROUND OF THE INVENTION

### 1. Field of the Invention

The present invention relates to a surface acoustic wave device, and more specifically, to a surface acoustic wave device which can reduce loss of energy.

### 2. Description of Related Art

A surface acoustic wave is an acoustic wave which propagates along the surface of an elastic substrate. Such an acoustic wave is generated from an electrical signal as a result of piezoelectric effect, and if the electric field of the acoustic wave concentrates around the surface of the substrate, the acoustic wave may interact with conductive electrons of another semiconductor, which is put right on the surface of the substrate. A medium which propagates the acoustic wave is a piezoelectric material having high electromechanical coupling coefficient and low acoustic wave energy loss, and the semiconductor is a material having high mobility of the conductive electrons and optimum resistivity, which can secure optimum efficiency as the DC power component is low. An electromechanical device which substitutes for an electronic circuit using interactions of the surface acoustic wave and the conductive electrons of a semiconductor is a SAW device.

The surface acoustic wave device like this (hereinafter, referred to as a SAW device) is used as an important part of a mobile communication phone and a base station, in addition to various communication applications. The most frequently used type of the SAW device is a pass band filter and a resonator. Owing to a small size and superior technical parameters (low loss, selectivity, etc.), as well as low price, the SAW device occupies practically a higher level of competitiveness compared with the devices based on other physical principles.

Particularly, as low insertion loss and high filtering performance are required recently in the field of SAW device application, various attempts have been made to reduce the insertion loss. However, a conventional method of reducing insertion loss is a method of adjusting the distance between electrodes or using a plurality of SAW devices, and the conventional method has a problem in that it is difficult to miniaturize since the overall size of a module using the SAW device increases.

Accordingly, development of a new technique which can reduce insertion loss and energy loss without increasing the size of a SAW device is required.

### SUMMARY OF THE INVENTION

Therefore, the present invention has been made in view of the above problems, and it is an object of the present invention to provide a SAW device structure which can reduce insertion loss.

In addition, another object of the present invention is to provide a SAW device which can pass signals having a wide pass band width with respect to a center frequency.

The technical problems of the present invention are not limited to those mentioned above, and unmentioned other technical problems may be clearly understood by those skilled in the art from the following descriptions.

To accomplish the above objects, according to one aspect of the present invention, there is provided a surface acoustic wave device including: a substrate; an electrode disposed on the substrate in a first direction; a dummy bar disposed to be spaced apart from the electrode by a predetermined distance in the first direction; and an additional film formed on the dummy bar, in which the electrode and the dummy bar are disposed in plurality in parallel in a second direction perpendicular to the first direction, and the dummy bars are alternately disposed on the left side or the right side of the electrode to be spaced apart from the electrode by the predetermined distance, and the additional film is formed on the predetermined distance between the electrode and the dummy bar and on the plurality of dummy bars.

According to an embodiment, thickness of the additional film may be a quarter to two times of thickness of the electrode.

According to an embodiment, the additional film may be formed to cover the dummy bars and at least a portion from an end of the electrodes adjacent to the dummy bars.

According to an embodiment, thickness of the additional film formed on the end of the electrode may be the same as thickness of the additional film formed on the predetermined distances between the electrodes and the dummy bars and on the plurality of dummy bars.

According to an embodiment, the SAW device may further include first and second reflectors disposed on both sides of the plurality of electrodes and dummy bars, and the additional film is formed to cover at least a portion from both ends of the first and second reflectors.

According to an embodiment, the additional film may be formed to cover the entire surface on which the first and second reflectors are disposed.

According to an embodiment, the predetermined distance may be between 100 nm and 1,000 nm.

According to an embodiment, the additional film may be formed of any one among silicon oxide SiO₂, silicon nitride Si₃N₂, aluminum oxide Al₂O₃, titanium oxide TiO₂, tantalum oxide Ta₂O₅, hafnium oxide HfO₂, aluminum Al, copper Cu, tungsten W, molybdenum Mo, and titanium Ti.

According to an embodiment, the second direction may be a direction the same as the propagation direction of the surface acoustic wave.

A surface acoustic wave device according to another embodiment of the present invention includes: a substrate; first and second bus bars disposed in parallel on the substrate; a plurality of first electrodes disposed to be extended from the first bus bar toward the second bus bar; a plurality of second electrodes disposed to be extended from the second bus bar toward the first bus bar; a dummy bar disposed in a first area between the plurality of first electrodes and second bus bars and a second area between the plurality of second electrodes and first bus bars; and an additional film formed on the first area and the second area.

### BRIEF DESCRIPTION OF THE DRAWINGS

FIG. 1 is a view showing the top surface of a SAW device according to a first embodiment of the present invention.

FIG. 2 is a view showing the cross-section of a SAW device and the speed of the surface acoustic wave of the SAW device according to a first embodiment of the present invention.

FIG. 3 is a view showing the top surface of a SAW device according to a second embodiment of the present invention.

FIG. 4 is a view showing the cross-section of a SAW device and the speed of the surface acoustic wave of the SAW device according to a second embodiment of the present invention.

FIGS. 5A and 5B are views showing the top surface of a SAW device including a reflector according to an embodiment of the present invention.

FIG. 6 is a view showing the top surface of a SAW device according to a third embodiment of the present invention.

FIG. 7 is a graph showing insertion loss of a resonator using a SAW device according to a second embodiment of the present invention.

FIG. 8 is a graph showing the frequency characteristic of a SAW device according to a second embodiment of the present invention.

FIG. 9 is a graph showing the Q characteristic with respect to the frequency of a SAW device according to a second embodiment of the present invention.

### DETAILED DESCRIPTION OF THE PREFERRED EMBODIMENT

Hereinafter, preferred embodiments of the present invention will be described in detail with reference to the accompanying drawings. Advantages and features of the present invention and a method for achieving the same will be more clearly understood with reference to the embodiments described below, together with the accompanying drawings. However, the present invention is not limited to the embodiments disclosed below, but may be implemented in various different forms. The embodiments are provided merely to complete disclosure of the present invention and to fully provide a person having ordinary skill in the art to which the present invention pertains with the category of the present invention. The present invention is defined only by the category of the claims. Wherever possible, the same reference numbers will be used throughout the specification to refer to the same or like parts.

Unless otherwise defined, all terms used in this specification (including technical and scientific terms) may be used as a meaning that can be commonly understood by those skilled in the art. In addition, the terms defined in a generally used dictionary are not to be ideally or excessively interpreted unless the terms are clearly and specially defined. The terms used in this specification are not to limit the present invention, but to describe the embodiments. In this specification, singular forms are intended to include plural forms as well, unless the context clearly indicates otherwise.

The terms “comprises” and/or “comprising” used herein specify that the stated components, steps, operations and/or elements do not preclude the presence or addition of one or more other components, steps, operations and/or elements.

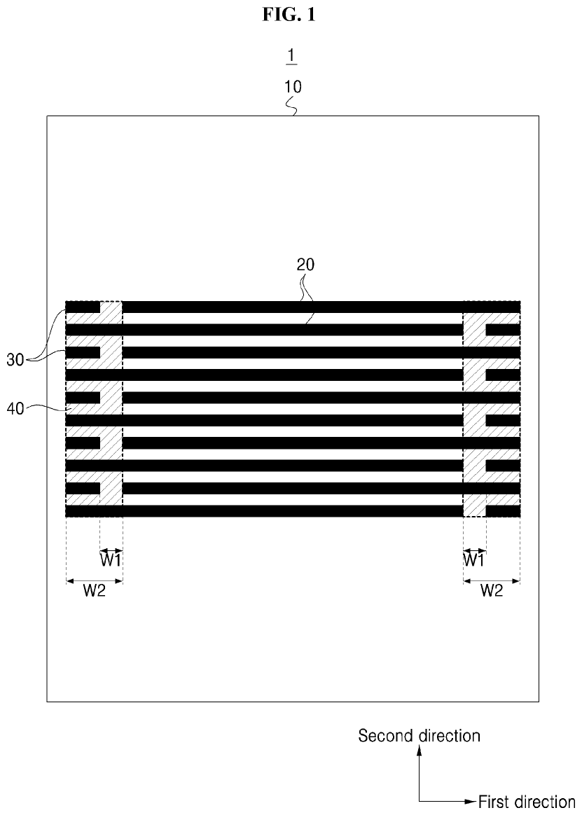

FIG. 1 is a view showing the top surface of a SAW device 1 according to a first embodiment of the present invention.

Referring to FIG. 1, a SAW device 1 may include a substrate 10, an electrode 20 disposed on the substrate 10, a dummy bar 30 disposed to be adjacent to the electrode 20, and an additional film 40 formed on the dummy bar 30.

The substrate 10 is formed of a material capable of providing piezoelectric effect, and for example, the substrate 10 may be any one among a silicon substrate, a diamond substrate, a sapphire substrate, a silicon carbide substrate, a LiNbO₃ substrate, and a LiTaO₃ substrate.

Next, the electrode 20 may be disposed on the substrate 10 in a first direction. The electrodes 20 may be disposed in plurality at regular intervals in a second direction perpendicular to the first direction and may be divided into an input electrode and an output electrode according to disposition of the dummy bar 30 described below.

Meanwhile, in the description of the present invention, the second direction perpendicular to the first direction may be a direction the same as the propagation direction of a surface acoustic wave, i.e., an acoustic wave, generated by the piezoelectric effect of the SAW device 1.

For reference, in the detailed description of the present invention, it is described on the assumption that the first direction is a horizontal direction and the second direction is a vertical direction to help understanding of the drawings.

The dummy bar 30 may be disposed in the first direction, the same as the direction of the electrode 20, to be spaced apart from the electrode 20 by a predetermined distance W1. In the case of a conventional SAW device 1, as a transverse wave perpendicular to the propagation direction of the surface acoustic wave is generated in the empty space W2 formed at the end of the electrode 20, loss of energy occurs in the surface acoustic wave flowing through the electrode 20 formed on the substrate 10. Accordingly, in the present invention, the insertion loss at the end of the electrode 20 may be minimized by disposing the dummy bar 30 at the end of the electrode 20 performing an input or output function.

According to embodiments, the predetermined distance W1 between the dummy bar 30 and the electrode 20 may be 100 to 1,000 nm.

In addition, a dummy bar 30 is disposed in the first direction to be spaced apart from an electrode 20 by a predetermined distance W1, and a plurality of dummy bars 30 and electrodes 20 may be disposed in the second direction. At this point, the intervals of the plurality of dummy bars 30 and electrodes 20 in the second direction may be regular, and the value of the regular intervals may vary according to setting of a resonance condition using the SAW device 1 by a user.

In addition, the dummy bars 30 are alternately disposed on the left and right sides of the electrodes 20, and each of the electrodes 20 may perform a function of an input electrode or an output electrode and allows the surface acoustic wave to propagate in the second direction.

Finally, the additional film 40 is formed on the dummy bar 30 and on the predetermined distance W1 between the dummy bar 30 and the electrode 20 (as much as the distance of W2) and may suppress energy loss of the surface acoustic wave flowing along the electrode 20, which occurs at the dummy bar 30 and the predetermined distance W1 between the electrode 20 and the dummy bar 30. More specifically, the energy loss means acoustic loss (leaky wave) of the surface acoustic wave according to generation of the transverse wave mentioned in the description of the dummy bar 30, and it is possible to reduce the propagation speed of the surface acoustic wave at the end of the electrode 20 and reduce the amount of energy consumed at the end of the electrode 20, by covering the dummy bar 30 and the predetermined distance W1 with the additional film 40 of a medium different from the air.

In addition, as the dummy bars 30 are alternately disposed on the left and right sides of the electrodes 20, the additional film 40 may be formed to configure a long pair on the left and right sides of the electrodes 20 in the second direction, and the first direction width W2 of the additional film 40 may be a value adding the first direction width of the dummy bar 30 and the first direction width of the predetermined distance W1 between the dummy bar 30 and the electrode 20.

According to embodiments, the additional film 40 like this may be formed of any one among silicon oxide SiO₂, aluminum oxide Al₂O₃, titanium oxide TiO₂, tantalum oxide Ta₂O₅, hafnium oxide HfO₂, aluminum Al, copper Cu, tungsten W, molybdenum Mo, and titanium Ti, and may be formed of various dielectric materials which can reduce the speed of the surface acoustic wave at the end of the electrode 20.

Until now, a SAW device 1 according to a first embodiment of the present invention has been briefly described seeing from the top, and hereinafter, the speed of the surface acoustic wave of the SAW device 1, which appears as the cross-section and the additional film 40 of the SAW device 1 are formed, will be described in detail.

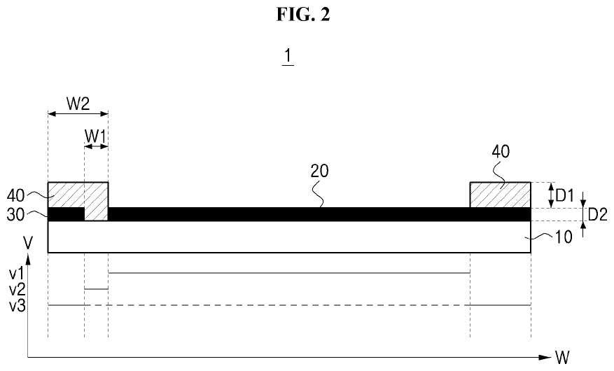

FIG. 2 is a view showing the cross-section of a SAW device 1 and the speed of the surface acoustic wave of the SAW device 1 according to a first embodiment of the present invention.

Referring to FIG. 2, thickness D1 of the additional film 40 included in the SAW device 1 may be larger than the thickness D2 of the electrode 20 and the dummy bar 30. Further preferably, the thickness D1 of the additional film 40 may have a value in a range of a quarter to two times of the thickness D2 of the electrode 20 and the dummy bar 30, and accordingly, energy loss of the surface acoustic wave generated at the end of the electrode 20 can be reduced.

Seeing the graph showing the speed V of the surface acoustic wave according to the position from the cross-sectional view of the SAW device 1, as the additional film 40 is formed on the predetermined distance W1 between the electrode 20 and the dummy bar 30 and on the dummy bar 30, the speed v2 of the surface acoustic wave at the end of the electrode 20 adjacent to the dummy bar 30 is reduced to be lower than the speed v1 of the surface acoustic wave at the electrode 20, and thus energy loss of the surface acoustic wave consumed at the end of the electrode 20 adjacent to the dummy bar 30 can be reduced.

Meanwhile, since the additional film 40 is formed as a pair on both sides of the electrode 20 as is when the additional film 40 of FIG. 1 is described, it is confirmed from the cross-section of FIG. 2 that the additional film 40 is formed at the other end of the electrode 20 that is not adjacent to the dummy bar 30. Accordingly, the speed v3 of the surface acoustic wave at the other end of the electrode 20 can be further reduced, and as the consumed energy of the surface acoustic wave is reduced, the characteristic of the SAW device 1 can be further enhanced.

Until now, a SAW device 1 according to a first embodiment of the present invention has been described. Hereinafter, an additional film 40 additionally formed in a predetermined area of the electrode 20 of the SAW device 1 will be described in detail.

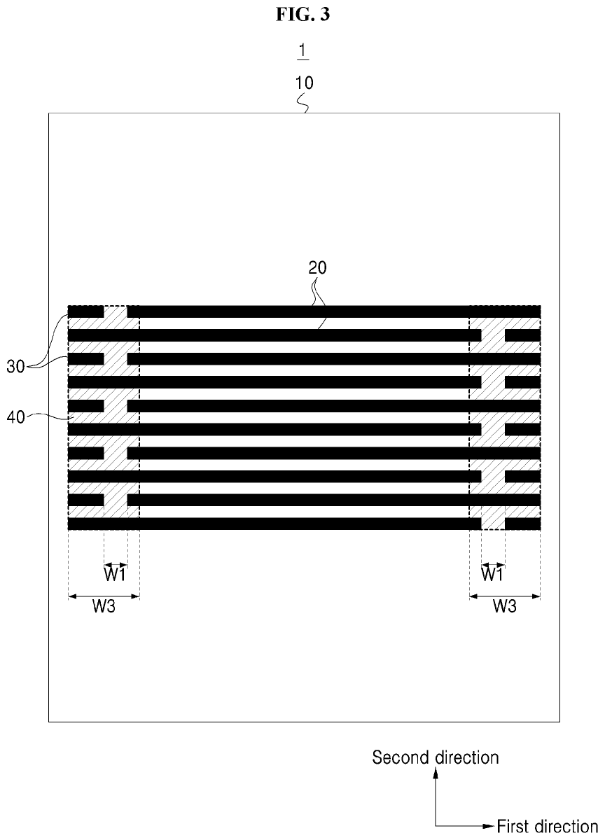

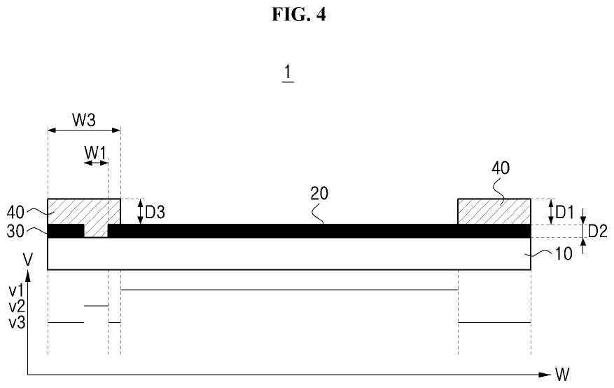

FIG. 3 is a view showing the top surface of a SAW device 1 according to a second embodiment of the present invention, and FIG. 4 is a view showing the cross-section of a SAW device 1 and the speed of the surface acoustic wave of the SAW device 1 according to a second embodiment of the present invention.

Referring to FIG. 3, the additional film 40 may be formed to cover at least a portion from the end of the electrode 20 adjacent to the dummy bar 30. In other words, the additional film 40 may cover the dummy bar 30, the predetermined distance W1 between the dummy bar 30 and the electrode 20, and at least an area from the end of the electrode 20 adjacent to the dummy bar 30. Accordingly, the first direction width W3 of the entire additional film 40 becomes larger than the width W2 of the additional film 40 according to a first embodiment, and the energy consumed at the end of the electrode 20 can be further reduced.

In relation to this, referring to FIG. 4, it is confirmed that as the additional film 40 is formed at the end of the electrode 20 adjacent to the dummy bar 30, the speed of the surface acoustic wave is further reduced compared with that of the additional film 40 formed as much as the predetermined distance W1 between the dummy bar 30 and the electrode 40, and energy loss of the surface acoustic wave can be reduced according thereto.

According to a second embodiment, the additional film 40 may be formed to cover the electrode 20 as much as 0.8 to 1.16λ from the end of the electrode 20 adjacent to the dummy bar 30. Here, 12 means a distance in the second direction from an input electrode and an output electrode of a surface acoustic wave to a next input electrode and a next output electrode, and more preferably, the additional film 40 may be formed to cover the end of the electrode 20 as much as 0.91λ.

In addition, as the thickness D3 of the additional film 40 formed at the end of the electrode 20 adjacent to the dummy bar 30 is formed to be the same as the thickness D1 of the additional film formed on the predetermined distance W1 between the electrode 20 and the dummy bar 30 and on the dummy bar 30, convenience in the process of manufacturing the SAW device 1 can be enhanced.

In addition, thickness D1 and D3 of the additional film 40 may larger than the predetermined distance W1 between the dummy bar 30 and the electrode 20.

Until now, a SAW device 1 according to a second embodiment of the present invention has been described. Hereinafter, an additional film 40 additionally formed even in a reflector area of the SAW device 1 will be described in detail.

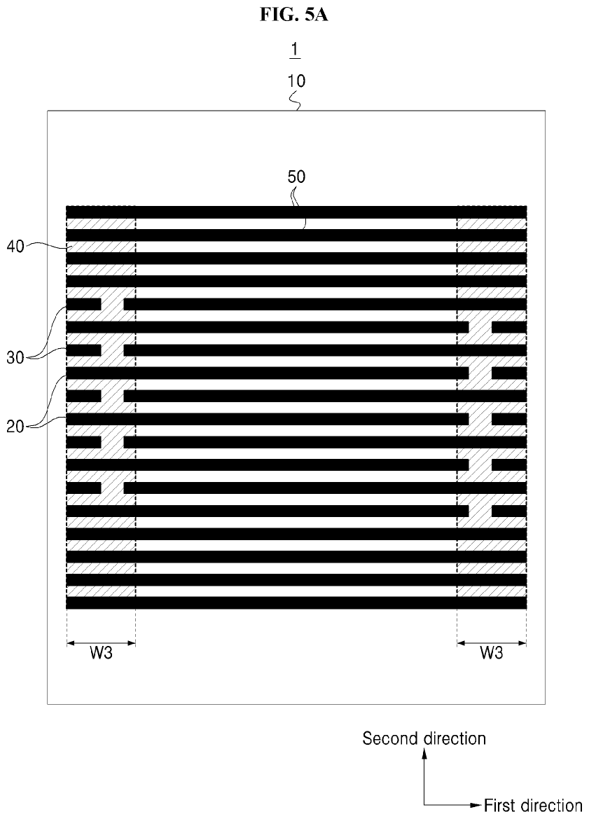

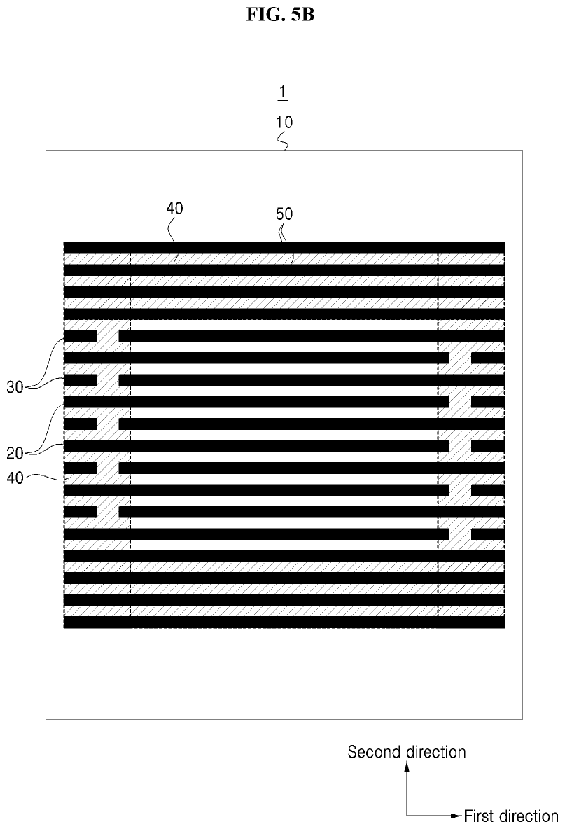

FIGS. 5A and 5B are views showing the top surface of a SAW device including a reflector according to an embodiment of the present invention.

Referring to FIGS. 5A and 5B, the SAW device 1 may further include first and second reflectors 50a and 50b disposed on both sides of a plurality of electrodes 20 and dummy bars 30 disposed in the second direction.

According to embodiments, the first and second reflectors 50a and 50b may include a plurality of bar-shaped electrodes disposed in parallel in the second direction. Meanwhile, in the present invention, although it is shown in the form of an open circuit in which both ends of the plurality of electrodes configuring the first and second reflectors 50a and 50b are not connected, the plurality of bar-shaped electrodes may be disposed in the form of a closed circuit connecting both ends of the plurality of electrodes or in the form of a positive and negative (PNR) grating which combines the open circuit form and the closed circuit form.

In addition, as the SAW device 1 includes the first and second reflectors 50a and 50b, the reflection characteristic of the surface acoustic wave of a resonator using the SAW device 1 can be enhanced. More specifically, insertion loss of the surface acoustic wave can be reduced by disposing the first and second reflectors 50a and 50b on both sides of the plurality of electrodes 20 and dummy bars 30 to reflect the surface acoustic wave which propagates along the plurality of electrodes 20 (second direction).

Meanwhile, the SAW device 1 of the present invention may form an additional film 40 on the first and second reflectors 50a and 50b, and accordingly, as the value of the electromechanical coupling factor K², which is vibration conversion efficiency of the SAW device 1, increases, an effect of increasing the pass band of the SAW device 1 can be obtained.

According to embodiments, the additional film 40 formed on the first and second reflectors 50a and 50b may be divided into two types. First, as shown in FIG. 5A, the additional film 40 may be formed to cover at least a portion from both ends of the first and second reflectors 50a and 50b. For example, the additional film 40 may be formed in a width the same as the width W3 of the additional film 40 covering as far as the end of the electrode 20 adjacent to the dummy bar 30. However, the width of the additional film 40 formed on the first and second reflectors 50a and 50b is not limited thereto and may have a width larger than W3.

Second, as shown in FIG. 5B, the additional film 40 may be formed to cover the entire surface of the SAW device 1 in which the first and second reflectors 50a and 50b are disposed. In this case, the value of the electromechanical coupling factor K² may be larger than that of the first case of covering the additional film 40 on both ends of the first and second reflectors 50a and 50b. More specifically, as the value of the electromechanical coupling factor K² increases, the pass band width of the SAW device 1 increases as much as 1 MHz or more, and thus the frequency characteristic of the SAW device 1 can be enhanced.

Until now, a SAW device 1 is described on the basis of a position where the additional film 40 of the present invention is formed. Hereinafter, the additional film 40 formed according to disposition of electrodes of the SAW device 1 will be described in detail.

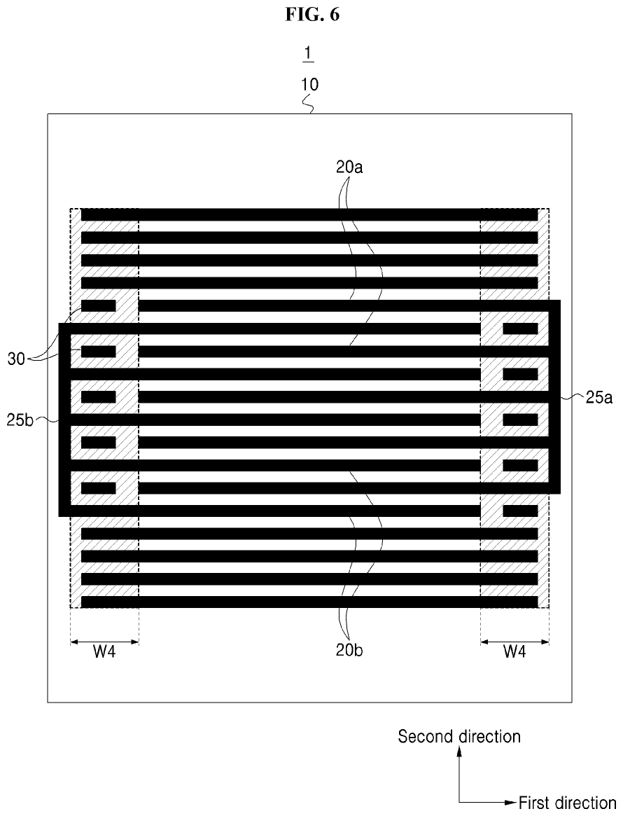

FIG. 6 is a view showing the top surface of a SAW device 1 according to a third embodiment of the present invention.

Referring to FIG. 6, a SAW device 1 according to a third embodiment of the present invention may include a substrate 10, first and second bus bars 25a and 25b disposed on the substrate 10, a plurality of first and second electrodes 20a and 20b formed to be extended from the first and second bus bars 25a and 25b, dummy bars 30 disposed between the first and second bus bars 25a and 25b, an additional film 40 formed on the dummy bars 30, and first and second reflectors 50a and 50b.

The substrate 10 may be formed of a material capable of providing a piezoelectric effect, like the substrate 10 according to a first embodiment of the present invention. For example, the substrate 10 may be any one among a silicon substrate, a diamond substrate, a sapphire substrate, a silicon carbide substrate, a quartz substrate, a LiNbO₃ substrate, and a LiTaO₃ substrate.

Next, the first and second bus bars 25a and 25b may be disposed on the substrate 10 in parallel in the second direction. At this point, the second direction may be a direction the same as the propagation direction of the surface acoustic wave.

Each of the first and second bus bars 25a and 25b may perform a function of an input electrode or an output electrode, and as the SAW device 1 includes a plurality of first and second electrodes 20a and 20b in the first direction perpendicular to the second direction, a pair of inter-digital transducer (IDT) electrodes may be configured. In addition, the plurality of first and second electrodes 20a and 20b may be alternately disposed, and the spaced distance in the second direction may vary according to setting of a resonance condition using the SAW device 1 by a user.

The dummy bars 30 may be disposed in a first area between the plurality of first electrodes 20a and the second bus bar 25b and a second area between the plurality of second electrodes 20b and the first bus bar 25a. For example, the first area and the second area are areas shown as the width W4 of the additional film 40, which can reduce energy loss of the surface acoustic wave by minimizing the empty space between the electrodes.

Next, the first and second reflectors 50a and 50b may be disposed on both sides of the plurality of first and second electrodes 20a and 20b and the dummy bars 30, and may reduce insertion loss of the surface acoustic wave by reflecting the surface acoustic wave propagating along the plurality of first and second electrodes 20a and 20b.

Finally, the additional film 40 may be formed in the first area between the plurality of first electrodes 20a and the second bus bar 25b and the second area between the plurality of second electrodes 20b and the first bus bar 25a. In other words, it is possible to reduce the propagation speed of the surface acoustic wave at the end of the plurality of first and second electrodes 20a and 20b and reduce the amount of consumed energy, by covering the predetermined distance W1 between the dummy bars 30 and the plurality of first and second electrodes 20a and 20b and the dummy bar 30 with the additional film 40 of a medium different from the air.

According to embodiments, the dummy bar 40 may cover as much as the first direction width W4 of the first and second areas in which the dummy bars 40 are disposed or to cover as much as the first and second electrodes 20a and 20b, and accordingly, the amount of consumed energy can be further reduced.

Meanwhile, the additional film 40 may be formed of any one among silicon oxide SiO₂, silicon nitride Si₃N₂, aluminum oxide Al₂O₃, titanium oxide TiO₂, tantalum oxide Ta₂O₅, hafnium oxide HfO₂, aluminum Al, copper Cu, tungsten W, molybdenum Mo, and titanium Ti, and may be formed of various dielectric materials which can reduce the speed of the surface acoustic wave at the end of the plurality of first and second electrodes 20a and 20b.

Until now, the positions of forming the additional film 40 according to diverse embodiments of the present invention and enhanced effects thereof have been briefly described, and hereinafter, it will be described through the results of various experiments that the characteristic of the SAW device 1 is enhanced as the additional film 40 is formed.

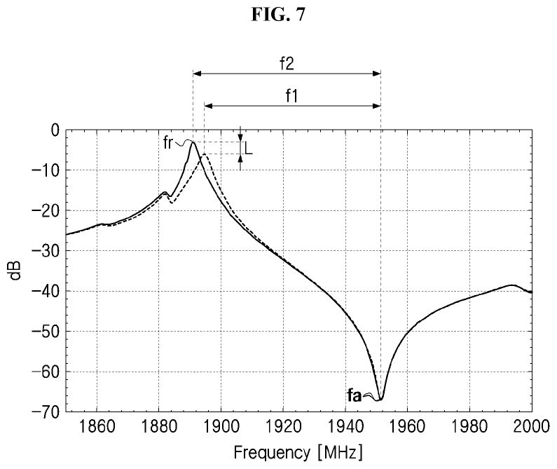

FIG. 7 is a graph showing insertion loss of a resonator using a SAW device 1 according to a second embodiment of the present invention.

Referring to FIG. 7, it is confirmed that the frequency characteristic according to resonance and anti-resonance of a resonator using the SAW device 1 is as shown below. Here, the horizontal axis denotes frequency MHz, the vertical axis denotes insertion loss dB, the solid line denotes an embodiment in which the additional film 40 of the present invention is formed, and the dotted line denotes a comparative example of the prior art, in which an additional film 40 is not formed.

According to a second embodiment, as the additional film 40 is formed on the predetermined distance W1 between the dummy bar 30 and the electrode 20 and on the end of the electrode 20 adjacent to the dummy bar 30, the SAW device 1 may have an insertion loss smaller than before at a resonance frequency fr. That is, it is confirmed that the insertion loss is reduced as much as L value compared with the insertion loss generated when the additional film 40 is not formed in the prior art, and the characteristic of the SAW device 1 can be enhanced.

Meanwhile, the vertical axis expressing insertion loss (dB) shows that the higher the value goes up, the more the characteristic of the SAW device 1 is enhanced. That is, it is understood that the higher the value on the vertical axis, the lower the insertion loss.

In addition, as the difference value f2 between the resonance frequency fr and the anti-resonance frequency fa in an embodiment of the present invention is larger than the difference value f1 between the resonance frequency fr and the anti-resonance frequency fa in the comparative example, the value of the electromechanical coupling factor K², which is vibration conversion efficiency of the SAW device 1, increases, and an effect of increasing the pass band of the SAW device 1 can be obtained.

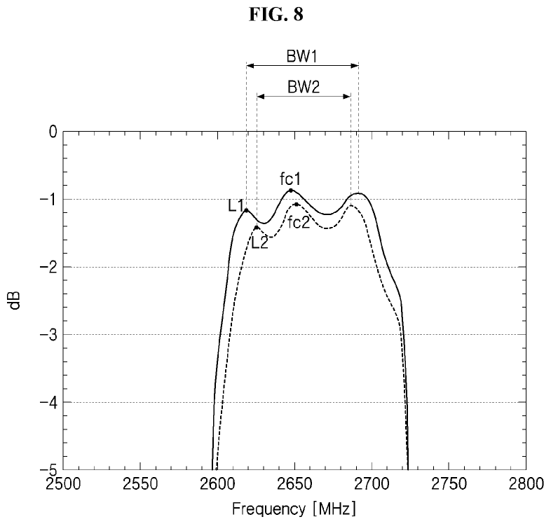

FIG. 8 is a graph showing the frequency characteristic of a SAW device 1 according to a second embodiment of the present invention.

Referring to FIG. 8, it is confirmed that the pass band according to the frequency of a filter using the SAW device 1 appears as shown below. Here, the horizontal axis denotes frequency MHz, the vertical axis denotes insertion loss dB, the solid line denotes an embodiment in which the additional film 40 of the present invention is formed, and the dotted line denotes a comparative example of the prior art, in which an additional film 40 is not formed.

According to a second embodiment, as the additional film 40 is formed on the predetermined distance W1 between the dummy bar 30 and the electrode 20 and on the end of the electrode 20 adjacent to the dummy bar 30, the maximum loss value L1 of a filter using the SAW device 1 is −1.272 dB, and the maximum loss value L2 of a conventional filter, in which an additional film 40 is not formed, is −1.439 dB, and thus it is confirmed that the maximum loss value of a filter using the SAW device 1 is decreased.

In addition, as the pass band (BW=117.3) with respect to the center frequency fc1 in an embodiment of the present invention becomes wider than the pass band (BW=112.1) with respect to the center frequency fc2 of a conventional filter, in which an additional film 40 is not formed, it is confirmed that the characteristic of the SAW device 1 is enhanced.

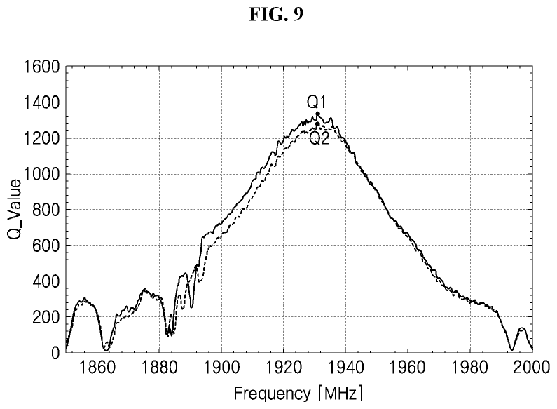

FIG. 9 is a graph showing the Q characteristic with respect to the frequency of a SAW device according to a second embodiment of the present invention.

Referring to FIG. 9, it is confirmed that the Q characteristic with respect to the frequency of a filter using the SAW device 1 appears as shown below. Here, the horizontal axis denotes frequency MHz, the vertical axis denotes Q-value, the solid line denotes an embodiment in which the additional film 40 of the present invention is formed, and the dotted line denotes a comparative example of the prior art, in which an additional film 40 is not formed.

According to a second embodiment, it is conformed that as the additional film 40 is formed on the predetermined distance W1 between the dummy bar 30 and the electrode 20 and on the end of the electrode 20 adjacent to the dummy bar 30, the Q characteristic value Q1 of a filter using the SAW device 1 has increased by approximately 50 compared with the Q characteristic value Q2 of a conventional filter in which an additional film 40 is not formed.

Like this, as the additional film 40 is formed on the predetermined distance W1 between the electrode 20 and the dummy bar 30 or beyond the predetermined distance W1, as far as the end of the electrode 20 adjacent to the dummy bar 30, an effect of reducing the insertion loss of the SAW device 1 and enhancing the characteristic as the pass band also increases can be obtained.

According to the present invention, insertion loss of the SAW device can be reduced by forming an additional film on an area in which an electrode and a dummy bar are disposed.

In addition, the characteristic of the SAW device can be enhanced by forming an additional film thicker than the electrode on an area in which the electrode and a dummy bar are disposed.

The effects of the present invention are not limited to those mentioned above, and unmentioned other effects may be clearly understood by those skilled in the art from the above descriptions.

Although embodiments of the present invention have been described with reference to the attached drawings, those skilled in the art may understand that the present invention can be embodied in other specific forms without changing the technical spirit or essential features thereof. Therefore, it should be understood that the embodiments described above are illustrative, not restrictive, in all aspects.

What is claimed is:

1. A surface acoustic wave device comprising:
a substrate;
an electrode disposed on the substrate in a first direction;
a dummy bar disposed to be spaced apart from the electrode by a predetermined distance in the first direction; and
an additional film formed on the dummy bar,
wherein the electrode and the dummy bar are disposed in plurality in parallel in a second direction perpendicular to the first direction, and the dummy bars are alternately disposed on a left side or a right side of the electrode to be spaced apart from the electrode by the predetermined distance, and the additional film is formed on the predetermined distance between the electrode and the dummy bar and on the plurality of dummy bars.

2. The device according to claim 1, wherein thickness of the additional film is a quarter to two times of thickness of the electrode.

3. The device according to claim 1, wherein the additional film is formed to cover the dummy bars and at least a portion from an end of the electrodes adjacent to the dummy bars.

4. The device according to claim 3, wherein thickness of the additional film formed on the end of the electrode is the same as thickness of the additional film formed on the predetermined distances between the electrodes and the dummy bars and on the plurality of dummy bars.

5. The device according to claim 1, further comprising first and second reflectors disposed on both sides of the plurality of electrodes and dummy bars, wherein the additional film is formed to cover at least a portion from both ends of the first and second reflectors.

6. The device according to claim 5, wherein the additional film is formed to cover an entire surface on which the first and second reflectors are disposed.

7. The device according to claim 1, wherein the predetermined distance is between 100 nm and 1,000 nm.

8. The device according to claim 1, wherein the additional film is formed of any one among silicon oxide SiO₂, silicon nitride Si₃N₂, aluminum oxide Al₂O₃, titanium oxide TiO₂, tantalum oxide Ta₂O₅, hafnium oxide HfO₂, aluminum Al, copper Cu, tungsten W, molybdenum Mo, and titanium Ti.

9. The device according to claim 1, wherein the second direction is a direction the same as a propagation direction of the surface acoustic wave.

10. A surface acoustic wave device comprising:
a substrate;
first and second bus bars disposed in parallel on the substrate;
a plurality of first electrodes disposed to be extended from the first bus bar toward the second bus bar;
a plurality of second electrodes disposed to be extended from the second bus bar toward the first bus bar;
a dummy bar disposed in a first area between the plurality of first electrodes and second bus bars and a second area between the plurality of second electrodes and first bus bars; and
an additional film formed on the first area and the second area.
